(19) United States
(12) Patent Application Publication
(10) Pub. No.: US 2014/0223734 A1
(43) Pub. Date: Aug. 14, 2014

(54) METHOD OF MANUFACTURING PROXIMITY SENSOR

(71) Applicant: LITE-ON SINGAPORE PTE. LTD., Midview City (SG)

(72) Inventors: GUANG-LI SONG, SINGAPORE (SG); SIN-HENG LIM, SINGAPORE (SG); TECK-CHAI GOH, SINGAPORE (SG)

(73) Assignee: LITE-ON SINGAPORE PTE. LTD., MIDVIEW CITY (SG)

(21) Appl. No.: 13/763,645

(22) Filed: Feb. 9, 2013

(51) Int. Cl. H05K 3/32

(52) U.S. Cl. CPC H05K 3/32
USPC 29/846

(57) ABSTRACT

The instant disclosure relates to a method of manufacturing proximity sensor includes the steps of providing a substrate having emitters and detectors disposed thereon. A sensor area is defined by one emitter with the adjacent detector. Wire bonding the emitters and detectors to the substrate for electrical connection. Molding a plurality of housings corresponds to each of the sensor areas and encapsulates the emitters and detectors. A shield having a plurality of apertures is provided and disposed atop the housings. After injection molding, an isolation layer is formed between the shield and substrate. Singulation is followed by injection molding to separate each of the sensor areas.

### BACKGROUND

1. Field of the Invention

The instant disclosure relates to a method of manufacturing proximity sensor; in particular, to utilize double molding and a shield.

2. Description of Related Art

A great variety of input control systems is available in the marketplace, for example, mouse, trackball and touch screen and a trend of applications employing touch screen is ever increasing. The touch panel is a visually transparent screen with high sensitivity toward touching and covers the operation area. The touch screen allows users to control the device by fingers or stylus and conducts associated calculation according to the touching event. Infrared (IR) proximity sensors are widely employed in mobile device to detect the distance between the user face and screen so to undergo different operation modes.

For example, when a mobile device is in idle, the proximity sensor is inactive and the screen is therefore shut and battery power saved. In contrast, during a phone call, a user face is nearby the screen yet the screen is locked to prevent from undesired button triggering. Additionally, the nominal range of the proximity sensor varies to fit desired requirement. For example, the proximity sensor with nominal range between 20 cm to 80 cm may be used in a monitor and detect nearby objects.

The proximity sensor includes an emitter and a detector and the conventional sensor employs housing material to encapsulate the emitter and detector. Moreover, metal shields are disposed atop to isolate undesired signal interference and prevent from cross-talk. However, issues arise in the fabrication of metal shields and assembly thereof. For instance, adhesive is needed to attach the metal shields on the housing; the use of adhesive determines the precision of the metal shield attachment. If more than sufficient adhesive is applied, the excessive glue may affect the adjacent components. On the other hand, if the adhesive is insufficient, the metal shield is prone to shift or detach which leads to the failure of signal isolation.

As the dimension of electronic components is ever decreasing, the assembly of smaller metal shield and housing requires even higher precision level to satisfy signal isolation. Hence the fabrication of proximity sensor remains a difficult process and improved reliability is also needed.

### SUMMARY OF THE INVENTION

The object of the instant disclosure is to provide a method of manufacturing proximity sensor. The method employs double molding and a shield to form a barrier between an emitter and a detector. Along with an existing housing, the shield rejects undesired signal interference and separates the emitter and detector in individual compartment.

According to one exemplary embodiment of the instant disclosure, the method of manufacturing proximity sensor includes steps of firstly, providing a substrate having a plurality of emitters and a plurality of detectors disposed thereon. Each of the emitters corresponds to one of the detectors together to define a sensor area. Secondly, wire bonding each of the emitters and detectors to the substrate for electrical connection. Then molding a plurality of housings on the substrate. Each of the housings encapsulates one sensor area which contains one emitter and one detector. Subsequently, providing a shield having a plurality of apertures conforming to individual emitters and detectors. Then injection molding forms an isolation layer between the substrate and shield. The isolation layer encloses the plurality of housings. Followed by the step of injection molding, dicing each of the sensor areas for proximity sensor singulation.

In summary, the instant disclosure in general reduces the manufacturing cost because of the low cost molds. The proximity sensor produced by the method is fittingly encapsulated and the interference is therefore blocked out therefore promoting the reliability. The double molding enhances the structural stability and reduces failure of shield attachment.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE DRAWINGS

FIG. 1 illustrates a schematic perspective view of a substrate having emitters and detectors thereon in accordance with the instant disclosure.

FIG. 2 illustrates a schematic perspective view of wire bonding in accordance with the instant disclosure.

FIG. 3 illustrates a schematic perspective view of a housing on a substrate in accordance with the instant disclosure.

FIG. 4 illustrates a schematic perspective view of a shield in accordance with the instant disclosure.

FIG. 5 illustrates a schematic perspective view of disposing a shield on a housing in accordance with the instant disclosure.

FIG. 6 illustrates a second molding in accordance with the instant disclosure.

FIG. 7 illustrates a schematic perspective view of dicing in accordance with the instant disclosure.

FIG. 8 illustrates a perspective view of a proximity sensor in accordance with the instant disclosure.

FIG. 9 illustrates an exploded view of a proximity sensor in accordance with the instant disclosure.

FIG. 10 illustrates a top cross-sectional view of a proximity sensor in accordance with the instant disclosure.

FIG. 11 illustrates a level cross-sectional view of a proximity sensor in accordance with the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

The instant disclosure provides a method of manufacturing proximity sensor by double molding and utilizing a shield therefore rejecting undesired signal interference. Furthermore, the method reduces manufacturing cost and minimizes failure rate.

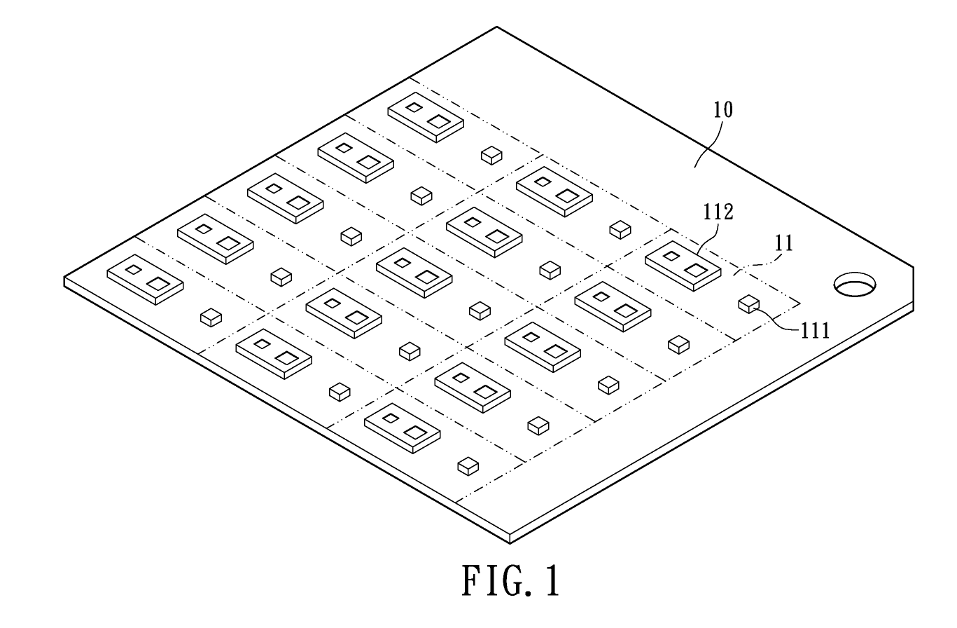

Attention is now invited to FIG. 1 showing a perspective view of fabricating a proximity sensor 1. First, a substrate 10, a plurality of emitter 111 and a plurality of detector 112 are provided. The emitters 111 and detectors 112 are alignedly disposed on the substrate 10 and the neighboring emitter 111 and detector 112 are grouped as a set. The set of emitter 111 and detector 112 defines a sensor area 11. Specifically, the emitters 111 and detectors 112 are mounted on the substrate 10 by die attaching. In other words, the substrate 10 is treated with epoxy or other adhesives and the emitters 111 and detectors 112 are precisely arranged thereon according to predetermined layout. Subsequently, excessive residues are removed by plasma cleaning. The emitter 111 is a light-emitting diode while the detector 112 is a photodiode. Furthermore, ambient light sensor may also be integrated to the existing proximity sensor 10. However, the emitters 111 and detectors 112 serve the job of responding to optical changes and are not limited to the aforementioned optical materials.

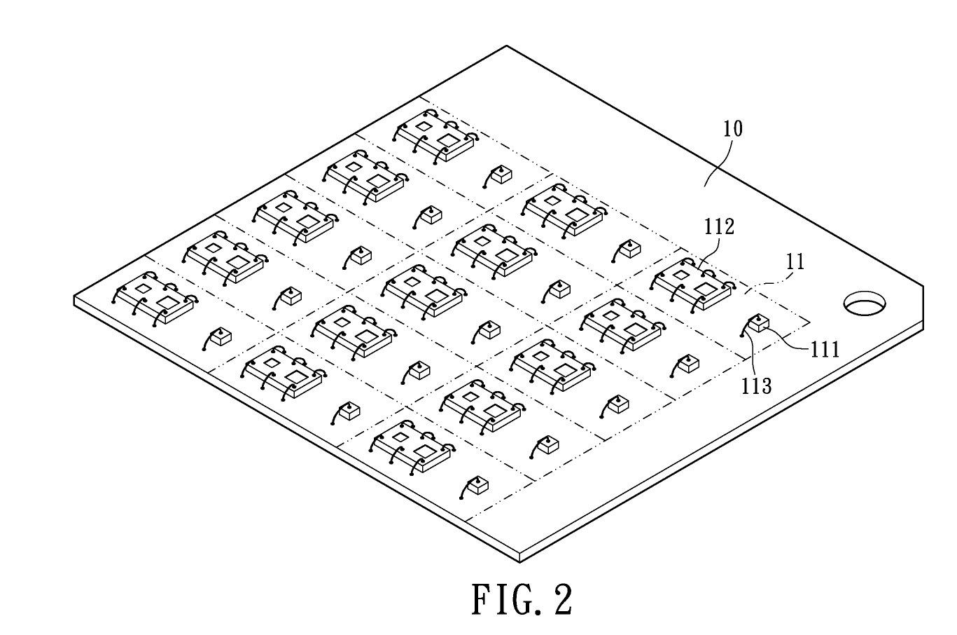

Attention is now invited to FIG. 2 showing a perspective view of wire bonding of the proximity sensor 1. Each of the emitters 111 and detector 112 within the sensor area 11 is wire bonded to the substrate 10 for electrical connection. A plurality of wires 113 is welded to the bonding pad (not shown) of the emitters 111 at one end and then the other end is welded to the corresponding location on the substrate 10. Similarly, the wires 113 are welded to the bonding pad (not shown) of the detectors 112 at one end and then the free end to the substrate 10. The wires 113 may be copper lead or the like which conducts electrical communication. The wire bonding step is followed by an inspection verifying bond quality and integrity of wires 113. A second plasma cleaning is conducted to rinse off the residues.

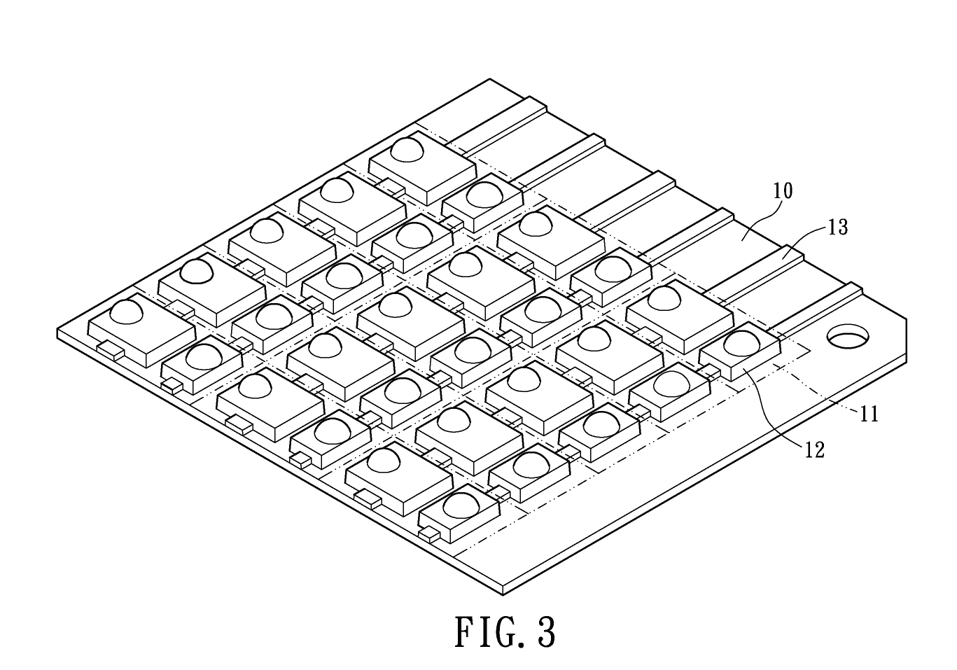

Attention now is invited to FIG. 3 showing a perspective view of a housing 12 molded on the substrate 10. In a first molding, a housing 12 is molded on the substrate 10. The housing 12 corresponds to the sensor area 11 and encapsulates the emitters 111 and detectors 112 separately. The housing 12 is made of optical transmissive material allowing, for example, infrared red rays going through. Specifically, in the first molding, a first mold (not shown) is utilized and the housing 12 is molded on the substrate 10 by injection molding. The filling material is fed to the substrate 10 through a first runner 13 and then cured next. Each of the emitters 111 and detectors 112 are individually encapsulated within the sensor area 11.

The molding material permits optical signal travelling so signals emitted from the emitter 111 are able to transmit through. On the other hand, the detector 112 receives signals through the housing 12 without rejection. In general the housing 12 does not attenuate the signal transmission through the proximity sensor 1. For example, if the detector 12 is integrated with an ambient light sensor, the molding material may be a clear molding material. If the detector 112 serves as a photodiode alone, the molding material may allow signal passage only to infrared rays. In other words, the molding materials vary according to the signal transmission requirement for the emitter 111 and detector 112 so to prevent from optical signal degradation within proximity sensor 1. Moreover, the housing 12 is configured to a slightly protruded shape conforming to the emitter 111 or detector 112 respectively which facilitates signal transmission. Next, a third plasma cleaning is conducted to remove excessive residues on the surface of substrate 10.

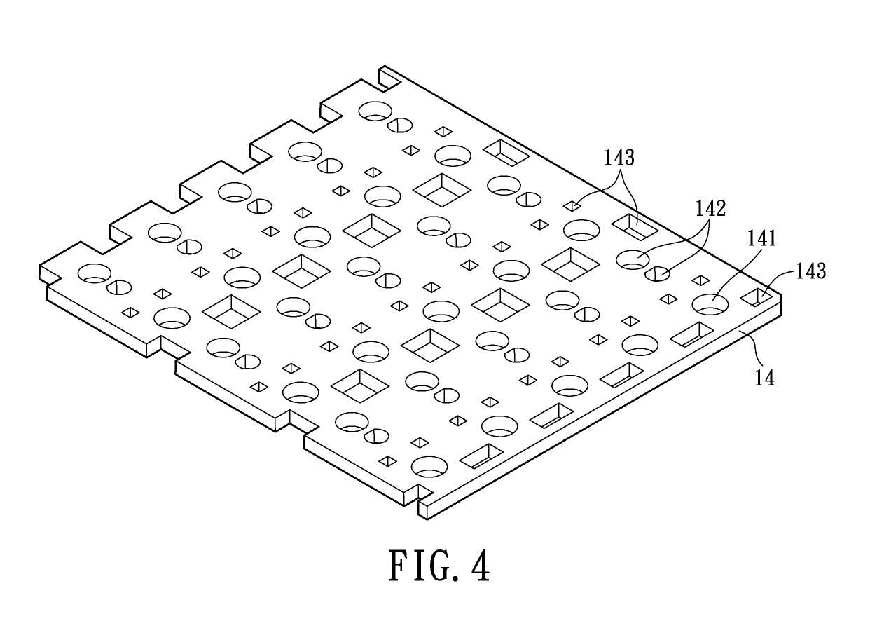

Attention now is invited to FIG. 4 showing a perspective view of a shield 14 utilized in the method. The shield 14, having a plurality of apertures corresponding to each of the emitters 111 and detectors 112, is provided. More specifically, the emission apertures 141 allow a portion of the emitters 111 signal for passing through. Likewise, the detection apertures 142 allow the detectors 112 for receiving a portion of desired signals. In addition, the shield 14 is formed with a plurality of filling channels 143 to receive, for example, epoxy, in a second molding. In the instant embodiment, each of the sensor area 11 contains one emitter 111 and therefore one corresponding emission aperture 141 is needed. In addition, the detector 112 may be proximity sensor alone or integrated with ambient light sensor so the detection aperture 142 may be one or two according to the sensor deposition. In order to scatter and receive the signals, the preferable shape of the emission and detection apertures 141, 142 is round and, however, the shape thereof is not limited thereto. For the filling channel 143, the preferable shape thereof is square yet not limited thereto. The quantity of the filling channel 143 may also vary for different manufacturing requirement.

The apertures on the shield 14 may be formed by stamping, laser cutting, casting or the like. The shield 14 serves the job of attenuating undesired optical interference to the emitters 111 and detectors 112 and therefore the material thereof may be metal or dark-colored (e.g. black) plastic. More specifically, the shield 14 can be made of aluminum, steel (e.g. SUS steel), epoxy, polyetheretherketone (PEEK), polyphenylene sulfide (PPS), infrared blocking acrylic or the like.

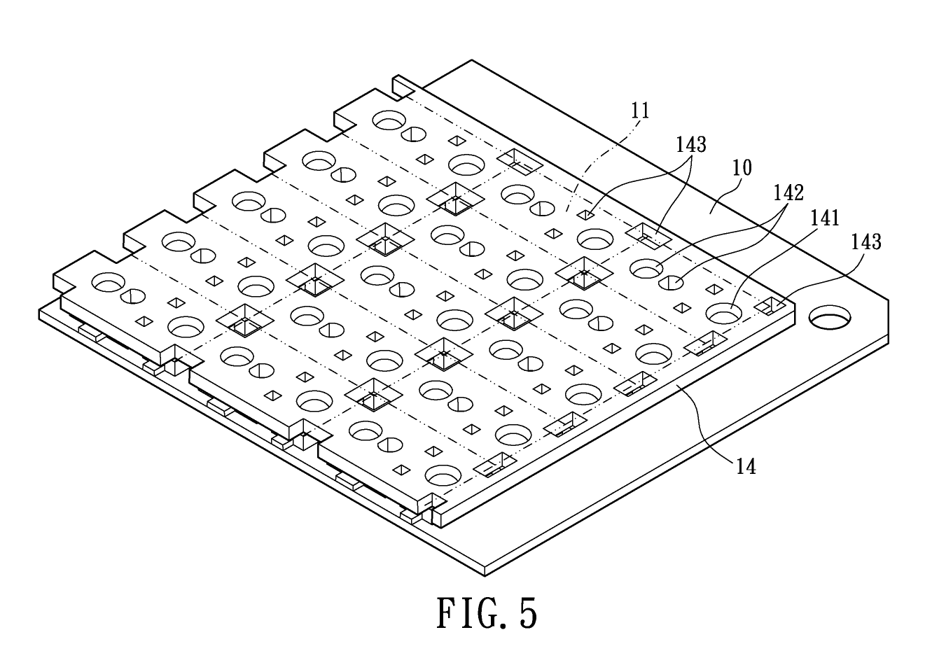

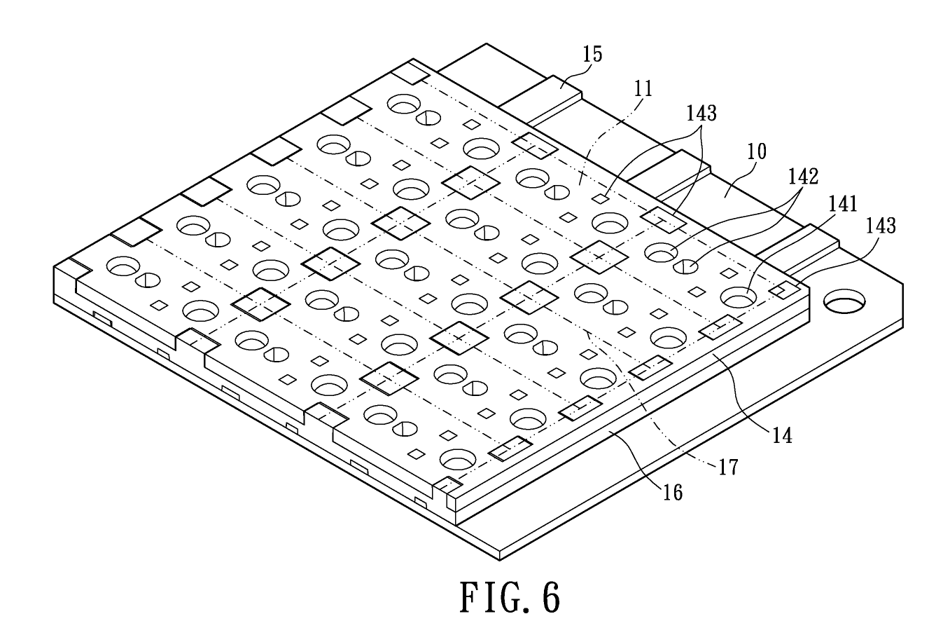

Attention now is invited to FIG. 5 in conjunction with FIG. 6. FIG. 5 shows a perspective view of disposing the shield 14 onto the housing 12 while FIG. 6 shows the second molding of the proximity sensor 1. In the second molding, the shield 14 is disposed atop the housing 12 and an isolation layer 16 is formed between the substrate 10 and shield 14 by injection molding. The isolation layer 16 further fills the space among the housing 12. More specifically, the shield 14 and substrate 10 are arranged within a second mold (not shown) and the second mold is sealed to proceed with thermosetting material injection. The thermosetting material is injected through a second runner 15 and spreads between the substrate 10 and shield 14. After injection, the isolation layer 16 is cured. The thermosetting material is infrared ray blocking so the isolation layer 16 acts as an infrared ray barrier. Followed by curing, the second runner 15 is removed. In the instant embodiment, the thermosetting material fills the filling channel 143 of the shield 14 as well and thus the isolation layer 16 tightly encloses the shield 14. In contrast, the emission and detection apertures 141, 142 are spared by the isolation layer 16 in the second molding so the signal passages are clear for emitters 111 and detectors 112. Additionally, the isolation layer 16 acts as the boundary between each of the emitters 111 and detectors 112 for preventing from signal cross-talk. Furthermore, variants of shield 14 layout may be utilized for different types of sensors.

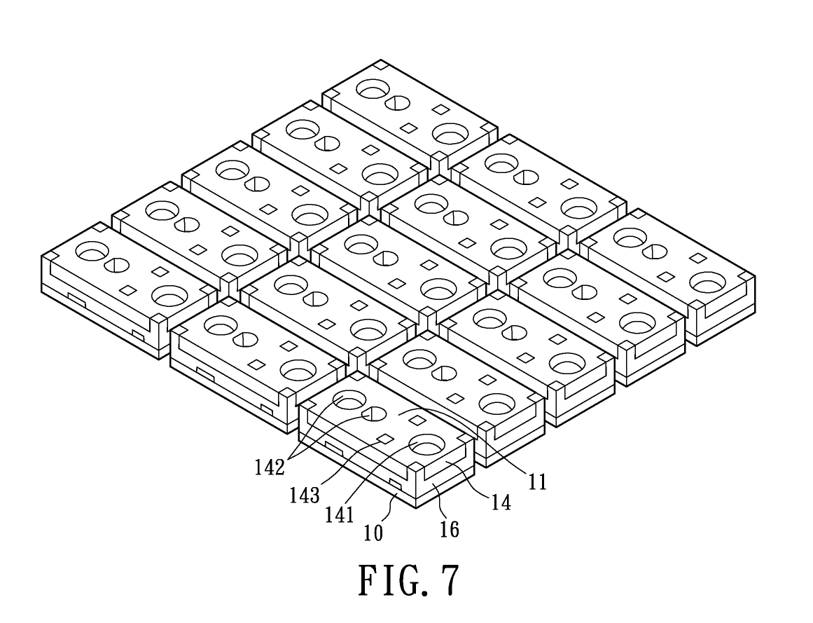

Attention now is invited to FIG. 7 showing a perspective view of dicing. After the step of second molding and curing, each of the sensor area 11 is separated by dicing. In the dicing step, thin blade or laser cutter is utilized for cutting along a cutting groove 17. The cutting groove 17 defines individual set of emitter 111 and detector 112 (i.e. a single sensor area 11). Sigulation of the proximity sensor 1 is then completed by the dicing.

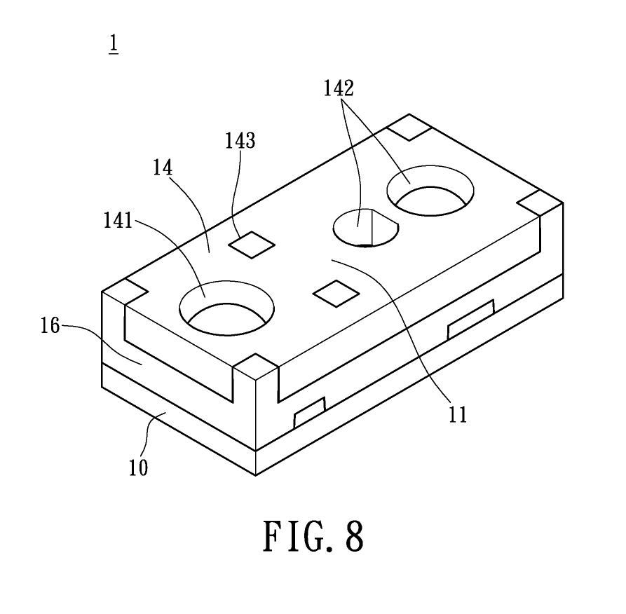

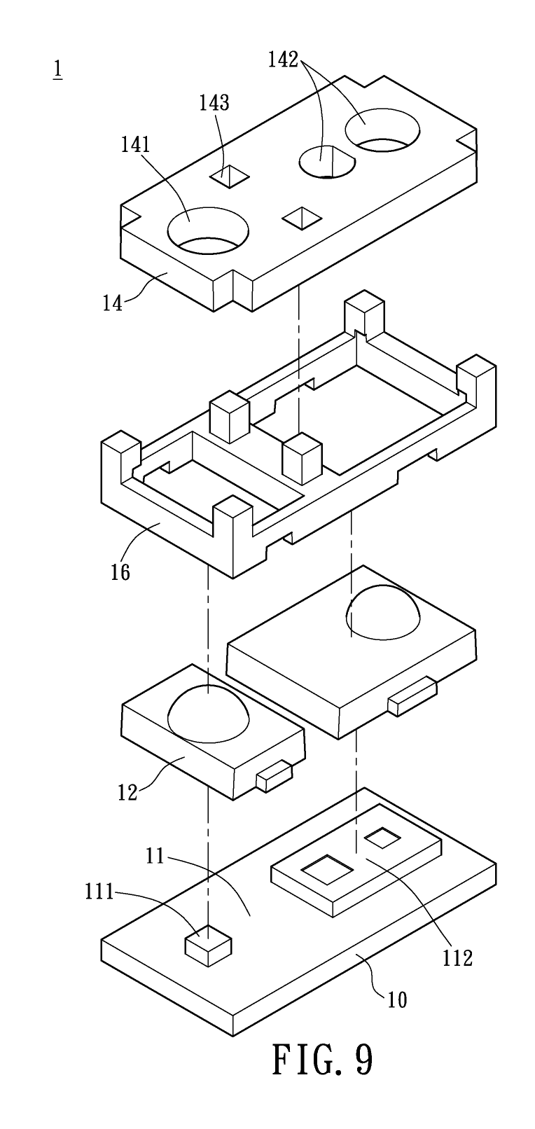

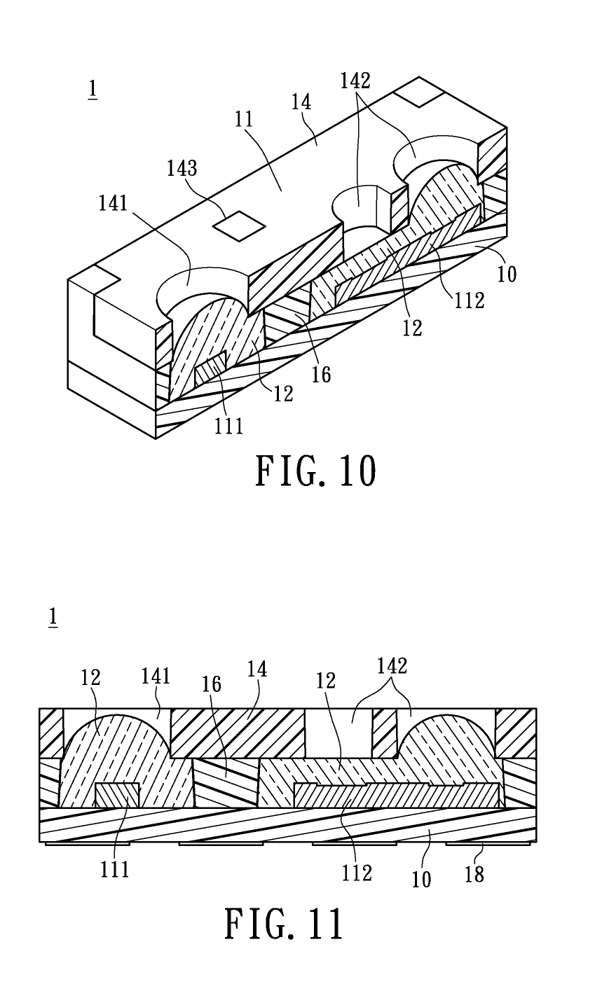

Attention is now invited to FIGS. 8˜11. FIGS. 8 and 9 show a perspective view of the proximity sensor 1. FIGS. 10 and 11 show a cross-sectional view of the proximity sensor from different perspectives. The proximity sensor 1, produced by the aforementioned steps, includes the substrate 10 having the emitter 111 and the detector 112 die attached and wire bonded thereon for electrical connection. The housing 12, which is mounted on the substrate 10, encloses the emitter 111 and detector 112 whereas the housing 12 structure may be modified to fit different types of emitter and detector. The material of the housing 12 is selected to permit different optical signal transmission, for example, ambient light permeability for integrated ambient light sensor. The isolation layer 16, which is made of infrared ray blocking material, fills the space between the substrate 10 and the shield 14 and surrounds the housing 12 to segregate undesired optical cross-talk interference. The shield 14 has apertures corresponding to the emitter 111 exit (i.e. emission aperture 141), detector 112 entrance (i.e. detection aperture 142) for signal transmission and the filling apertures 143 for thermosetting material injection. Additionally, a plurality of wire bond pads 18 are formed on the surface of substrate 10 opposite to the emitters 111 and detectors 112. The wire bond pads 18 can be electrically connected to the emitters 111 and detectors 112 for control signal and power transmission.

In summary, the molds are low cost and the absence of assembly equipment further reduces the manufacturing cost. The method provided in the instant disclosure yields reliable proximity sensors able to reject optical interference and isolate individual emitters as well as detectors. The double molding process enhances the structural stability therefore the associated components and housing tightly secured on the substrate.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A method of manufacturing proximity sensor comprising:
providing a substrate having a plurality of emitters and a plurality of detectors mounted alignedly thereon, each pair of immediately adjacent emitter and detector defining a sensor area;
wire bonding each of the emitters and detectors to the substrate to establish electrical connection;
effecting a first molding process for molding a plurality of housings on the substrate, the housings encapsulating each of the emitters and detectors respectively;
providing a shield having a plurality of apertures conforming to individual emitters and detectors;
effecting a second molding process through injection molding to form an isolation layer between the substrate and shield, the isolation layer enclosing the plurality of housings; and
dicing each of the sensor areas for proximity sensor singulation.

2. The method of manufacturing proximity sensor according to claim 1, wherein the plurality of emitters and detectors are die attached onto the substrate.

3. The method of manufacturing proximity sensor according to claim 1, wherein the plurality of emitters is light-emitted diode whereas the plurality of detectors is photodiode selectively integrated with ambient light sensors.

4. The method of manufacturing proximity sensor according to claim 1, wherein in the step of wire bonding, a plurality of wires is welded to the emitters and detectors firstly and then to the corresponding sensor areas to establish electrical circuits.

5. The method of manufacturing proximity sensor according to claim 1, wherein the housings are made of transparent materials allowing infrared ray permeability.

6. The method of manufacturing proximity sensor according to claim 1, wherein the shield apertures includes a plurality of emission apertures, a plurality of detection apertures and a plurality of filling channels.

7. The method of manufacturing proximity sensor according to claim 1, wherein the shield apertures are formed by stamping, laser cutting or casting.

8. The method of manufacturing proximity sensor according to claim 1, wherein the shield is made of metal or plastic.

9. The method of manufacturing proximity sensor according to claim 1, wherein the isolation layer is made of infrared ray blocking materials.

10. The method of manufacturing proximity sensor according to claim 1, wherein each of the sensor areas is separated by a plurality of cutting grooves and in the step of dicing a thin saw or laser cutter is utilized to divide each of the proximity sensors along the cutting grooves.
